(19) United States
(12) Patent Application Publication
(10) Pub. No.: US 2026/0109122 A1
(43) Pub. Date: Apr. 23, 2026

(54) METHOD OF MANUFACTURING MICROGASKET FOR RECONNECTABLE IMPLANTABLE DEVICE

(71) Applicant: University of Florida Research Foundation, Incorporated, Gainesville, FL (US)

(72) Inventors: Jack William JUDY, Gainesville, FL (US); Paritosh RUSTOGI, Gainesville, FL (US)

(21) Appl. No.: 19/125,548

(22) PCT Filed: Nov. 8, 2023
(86) PCT No.: PCT/US2023/079121

§ 371 Date: Apr. 29, 2025

Related U.S. Application Data
(60) Provisional application No. 63/382,932, filed on Nov. 9, 2022.

(51) Int. Cl. B29D 99/00; B29K 83/00; H05K 5/06

(52) U.S. Cl. CPC B29D 99/0053; H05K 5/061; B29K 2083/00; B29K 2995/0006

(57) ABSTRACT

Various embodiments of the present disclosure provide devices and methods of manufacturing. An example method includes forming a plurality of conductive elements on a surface of a substrate. The plurality of conductive elements are arranged along a first direction and a second direction. Respective first height dimensions of respective conductive elements are parallel to a third direction. The method includes compressing, in the third direction, the plurality of conductive elements using a planar component. The compressing adjusts the respective first height dimensions to respective second height dimensions. The method includes injecting a dielectric material between the substrate and the planar component. Injecting the dielectric material forms a dielectric layer around and in contact with the plurality of conductive elements. The substrate and the planar component may then be removed.

### CROSS REFERENCE TO RELATED APPLICATIONS

This application claims priority to U.S. Appl. No. 63/382,932, filed Nov. 9, 2022, the contents of which are incorporated herein in its entirety by reference.

### STATEMENT OF SUPPORT

This invention was made with government support under Grant Number R21 EB028079, awarded by the National Institutes of Health. The government has certain rights in the invention.

### TECHNICAL FIELD

The present application relates to the technical field of electrical connectors. In particular, the invention relates to a microgasket for a reconnectable device and its method of manufacturing.

### BACKGROUND

Demands for implantable bioelectronic devices to increase the number of channels for greater functional capacity and resolution, shrink implant size to minimize tissue response and patient burden, and support battery changes and electronics upgrades for long-term operational viability, may not be met with existing implant-connector technology. Some neural implant systems are being used to facilitate experiments that could advance fundamental knowledge of brain activity and brain function in normal, diseased, and injured states. The incentive to create higher channel count implantable neural interfaces for recording and stimulating neural activity has been driven by the need to increase the spatial resolution of the interfaces for different tissue targets. Typically, neural interfaces that have a high channel count and high channel density are connected to implanted, hermetically packaged electronics by an array of permanent bonds. However, since interfaces with a high channel count are frequently integrated intimately into delicate neural tissue, the explantation of the full implant system to replace batteries or electronics may lead to considerable damage to the neural tissue immediately surrounding the interface. To avoid this problem, some low channel count implants, such as deep-brain-stimulation devices and cardiac pacemakers, use implantable connectors that may be used numerous times without a degradation in performance. Reusable implantable connectors enable the interface to be detached from the implanted hermetic electronics enclosure. Doing so allows for battery changes and electronics upgrades to be performed without disturbing the delicate engagement between the tissue and the implanted interface (i.e., electrode arrays).

Implantable connectors based on a one-dimensional array of cylindrical electrical contacts are found in clinical devices. With this connector design, cylindrical contacts are integrated into the proximal end of a flexible lead that itself is inserted into an enclosure-integrated header that has a one-dimensional array of toroidal-shaped springs. Channel-to-channel isolation is achieved with a linear array of compressible insulating toroidal bushings that are integrated between the toroidal springs in the header. The individual bushings in the linear array are radially compressed sequentially when the lead is inserted. The tight fit that forms between the mating parts keeps the lead centered and resists the flow of electrical current between adjacent channels despite being immersed in a conductive saline solution. This approach may reliably maintain electrical connections and electrically isolate neighboring channels, while also being easy to handle and reconnectable for the replacement of batteries and/or electronics. Although this approach for implantable connectors has been successful and may be found in commercial devices, the underlying technology has not advanced significantly for many years. The low density of channels (i.e., ˜0.0644 channels per square millimeter (ch/mm²) prevents the development of small, high-channel-count implementations. To serve the needs of next-generation bioelectronic implants that require an increasingly large numbers of channels in an upgradable and miniature form factor, a new implant connector technology is needed that may achieve both high channel density and high channel-to-channel impedance (e.g., industry standard for deep brain stimulation (DBS) is greater than 50 kiloohms (k(Ω) for stimulation and greater than 1 megaohm (MΩ) for recording). Some interfaces may be directly connected with implant electronics by permanent-bonding techniques, such as those used prominently by the commercial microelectronics industry (e.g., aligned flip-chip bonding, anisotropic conductive adhesive, conventional wire bonding, etc.), which may prevent battery changes or implant upgrades without explanting the entire implant, including the interface integrated into delicate neural tissue.

### BRIEF SUMMARY

In one embodiment, a method includes forming a plurality of conductive elements on a surface of a substrate, the plurality of conductive elements arranged along a first direction parallel to the surface of the substrate and a second direction parallel to the surface of the substrate, wherein respective first height dimensions of respective conductive elements are parallel to a third direction; compressing, in the third direction, the plurality of conductive elements using a planar component, wherein the compressing adjusts the respective first height dimensions to respective second height dimensions; injecting a dielectric material between the substrate and the planar component, wherein injecting the dielectric material forms a dielectric layer around and in contact with the plurality of conductive elements; and removing the substrate and the planar component.

In one embodiment, an apparatus includes at least one processor; and at least one memory storing instructions that, when executed by the at least on processor, cause the apparatus to: form a plurality of conductive elements on a surface of a substrate, the plurality of conductive elements arranged along a first direction parallel to the surface of the substrate and a second direction parallel to the surface of the substrate, wherein respective first height dimensions of respective conductive elements are parallel to a third direction; compress, in the third direction, the plurality of conductive elements using a planar component, wherein the compressing adjusts the respective first height dimensions to respective second height dimensions; inject a dielectric material between the substrate and the planar component, wherein injecting the dielectric material forms a dielectric layer around and in contact with the plurality of conductive elements; and remove the substrate and the planar component.

In one embodiment, an apparatus includes an enclosure component comprising a cavity for a plurality of electronic components, wherein (i) a height of the enclosure component is parallel to a first direction, (ii) a width of the enclosure component is parallel to a second direction, and (iii) a depth of the enclosure component is parallel to a third direction; a header in contact with the enclosure component, the header comprising a first plurality of cavities extending through the header in the first direction; a first plurality of conductive elements formed in the first plurality of cavities, wherein one or more electronic components of the plurality of electronic components are electrically coupled with one or more conductive elements of the first plurality of conductive elements; a gasket in contact with a top surface of the header with respect to the first direction, the gasket comprising a second plurality of cavities extending through the gasket in the first direction; a second plurality of conductive elements formed in the second plurality of cavities, wherein the second plurality of conductive elements are in contact with the first plurality of conductive elements; and an interface component in contact with a top surface of the gasket with respect to the first direction, the interface component comprising a plurality of contact pads in contact with the second plurality of conductive elements.

### BRIEF DESCRIPTION OF THE DRAWINGS

Reference will now be made to the accompanying drawings, which are not necessarily drawn to scale, and wherein:

FIG. 1 illustrates an exemplary implantable connector assembly, according to one or more embodiments described herein;

FIG. 2 illustrates exemplary conductive element assemblies, according to one or more embodiments described herein;

FIG. 3 illustrates exemplary clamping configurations, according to one or more embodiments described herein;

FIG. 4 illustrates an exemplary test configuration, according to one or more embodiments described herein;

FIG. 5 illustrates exemplary microgasket cross sections, according to one or more embodiments described herein;

FIG. 6 illustrates an exemplary fabrication process, according to one or more embodiments described herein;

FIG. 7 illustrates an exemplary fabrication process, according to one or more embodiments described herein;

FIG. 8 illustrates an exemplary conductive element, according to one or more embodiments described herein;

FIG. 9 illustrates an exemplary stencil printing system, according to one or more embodiments described herein;

FIG. 10 illustrates an exemplary flood printing system, according to one or more embodiments described herein;

FIG. 11 illustrates exemplary aspect ratio configurations, according to one or more embodiments described herein;

FIG. 12 illustrates an exemplary table, according to one or more embodiments described herein;

FIG. 13 illustrates an exemplary microgasket fabrication system, according to one or more embodiments described herein;

FIG. 14 illustrates exemplary conductive element configurations, according to one or more embodiments described herein;

FIG. 15 illustrates an exemplary microgasket fabrication system, according to one or more embodiments described herein;

FIG. 16 illustrates an exemplary microgasket, according to one or more embodiments described herein;

FIG. 17 illustrates an exemplary microgasket fabrication system, according to one or more embodiments described herein; and

FIG. 18 illustrates a schematic of a computing entity that may be used in conjunction with one or more embodiments of the present disclosure.

### DETAILED DESCRIPTION

In accordance with examples as described herein, a high-channel-count implantable device is provided that may be serviced (e.g., for battery changes, electronics upgrades, etc.) without explantation. In one example, the device may include a microgasket (e.g., a gasket), which may have excellent electrical channel-to-channel isolation, despite long-term immersion in conductive body fluids. In one example, electrochemical impedance spectroscopy (EIS) may be utilized to assess the electrical isolation provided by the microgasket over a frequency range utilized in neurotechnology (i.e., 0.1 hertz (Hz) to 10 kilohertz (kHz)). In some examples, a thickness of the microgasket (e.g., a height of the microgasket) may be selected such that the microgasket maintains its shape when clamped under high clamping pressures or such that a deformation of the microgasket is below a threshold deformation. The microgasket may be made of a polymer material, such as polydimethylsiloxane elastomer (PDMSe or PDMS), which may provide superior electrical isolation for neural stimulation (˜5 megaohms (MΩ) at 10 kHz) when compared with conventional implant connectors (e.g., providing ˜50 kiloohms (kΩ) at 10 kHz), despite the microgasket providing a 200-fold increase in channel density (conventional: ˜0.0644 channels per square millimeter (ch/mm²), microgasket: ˜12.8 ch/mm²). The microgasket may also provide high electrical isolation for neural recording (i.e., ˜35 MΩ at 1 kHz) at the same high channel density. When mechanically compressed the microscale vias (e.g., cavities, holes) in the PDMSe microgasket may deform laterally, which may enhance gasket-traversing conductive spring elements in each microscale via. In some examples, one or more dimensions, such as a height-to-width aspect ratio of the microgasket vias, may be selected to improve performance of the microgasket when clamped. For example, a height-to-width aspect ratio may be selected that enables the microgasket vias to maintain their shapes within a threshold range under clamping pressure sufficient to create a seal using the microgasket.

### I. Exemplary Device

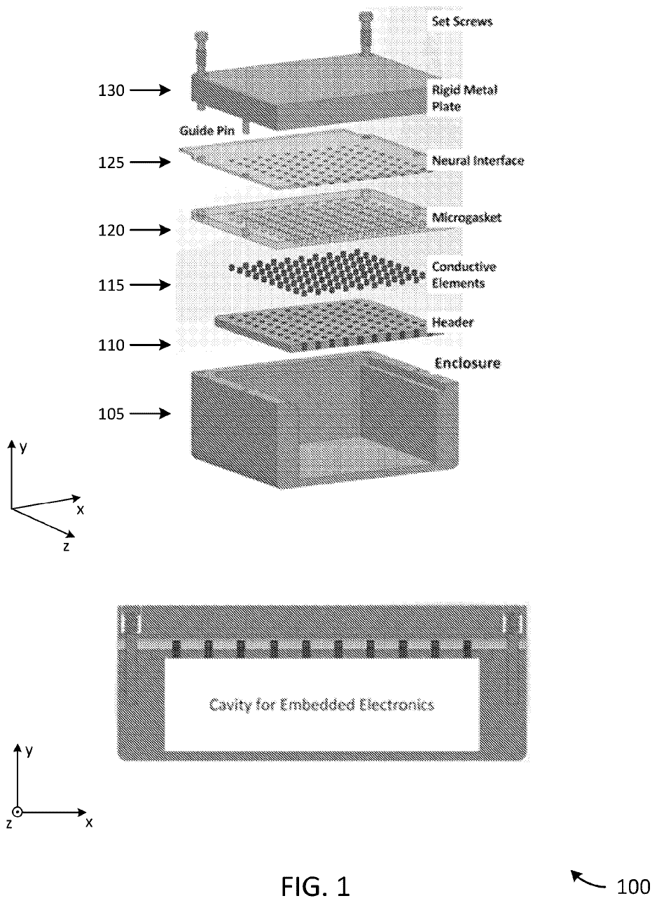

FIG. 1 illustrates an example of an implantable connector assembly 100, according to one or more embodiments of the present disclosure. The implantable connector assembly 100 may include an enclosure 105 (e.g., an enclosure component) for electronics (e.g., for one or more electronic components). The enclosure 105 may be hermetically bonded to a ceramic header 110 that includes an integrated, high-density feedthrough array (e.g., a first plurality of conductive elements formed in a first plurality of cavities). The implantable connector assembly 100 may include a microgasket 120 with micromachined holes (e.g., a second plurality of cavities) aligned to the header feedthroughs. The implantable connector assembly 100 may include a contact-pad array of a flexible neural interface 125 (e.g., an interface component) aligned to the gasket holes, an array of conductive elements 115 (e.g., a second plurality of conductive elements) individually bridging the vertical gap between the aligned arrays of header feedthroughs and neural-interface contact pads, and a rigid plate 130 (e.g., a plate component) to compresses the assembly together with screws and springs. Contact pads in the interface 125 may be electrically connected with corresponding feedthroughs in the header 110 with mechanically compressible conductive elements 115.

Connections made between individual contact pads on the neural interface 125, compressible conductive elements 115, and metal feedthroughs in the ceramic header 110 may be electrically isolated by the microgasket 120. Pressure applied by the rigid plate 130 and screws will be used to clamp the assembly, deform the micro-gasket 120 to achieve good electrical isolation, and compress the conductive elements 115 to achieve electrical connection.

The microgasket 120 may seal the enclosure 105 when pressure is applied to the microgasket 120 (e.g., when the assembly is clamped using the metal plate 130). In such examples, the clamping force may cause one or more components of the assembly 100, such as the gasket 120, to conform to the other surfaces in contact with the microgasket 120. For example, when pressure is applied to the connector assembly 100, the microgasket 120 may be compressed and may conform to the neural interface 125 and the header 110. Under higher pressures, the microgasket 120 may conform to adjacent surfaces more intimately (i.e., fill in the topographic surface features). As a result, the number and size of unfilled voids between the microgasket 120 and the adjacent surfaces (i.e., ceramic header 110 and the neural interface 125) may be reduced.

In some examples, the microgasket 120 may provide electrical isolation between one or more components of the assembly 100. For example, the microgasket 120 may electrically isolate one or more electronic components in the enclosure 105. Additionally, or alternatively, the microgasket 120 may electrically isolate conductive elements 115 from one another. Experiments are described herein that quantify the ability of compressed PDMSe (e.g., the micro-gasket 120) to provide electrical isolation to a device submerged in a conductive, physiological saline environment.

Although the microgasket 120 is designed to provide high electrical impedance between adjacent channels and the surrounding conductive solution (e.g., saline), the vertical vias through the microgasket 120 may enable opposing pairs of aligned interface-contact pads and header-feedthrough pads to be physically and electrically connected by individual compressible conductive elements 115 in each via. The compressible conductive elements 115 may be designed to achieve multiple points of contact for increased reliability and to maintain a contact force sufficient to reliably maintain low contact resistance. As described herein, the implantable connector assembly may be described or shown with reference to a first direction (e.g., a y-direction), a second direction (e.g., an x-direction), and a third direction (e.g., a z-direction).

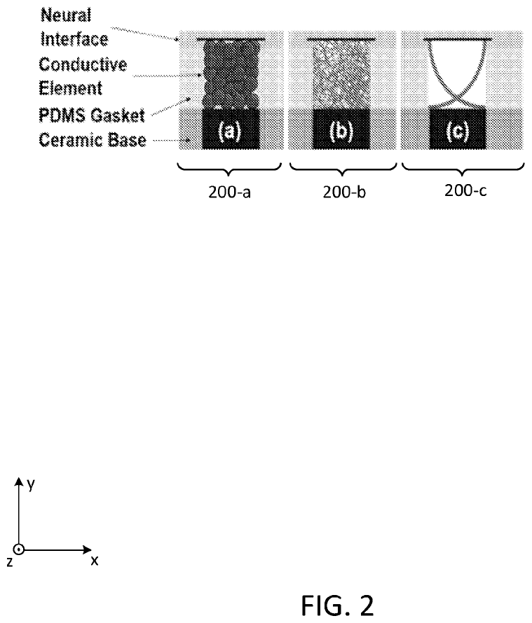

FIG. 2 illustrates example conductive element assembles 200, according to one or more embodiments of the present disclosure. Each of the conductive element assemblies 200 may illustrate a respective candidate approach for implementing compressible conductive elements (e.g., the second plurality of conductive elements). The candidate approaches for implementing compressible conductive elements may include: (a) conductive micro/nanoparticles embedded in a compressible material, (b) conductive electro spun fibers embedded in a compressible material and (c) conductive microfabricated spring elements using photolithography. In some examples, geometric changes to the microgasket observed during its compression may impact some approaches used to implement compressible conductive elements. Therefore, the present disclosure quantifies the geometric changes that occur when the gasket is compressed. In some examples, during replacement of batteries/electronics, a major priority is proper functioning of the connector (e.g., the connector assembly including the microgasket) after reconnection. Integrating the microgasket with the header and enclosure, which may be replaced during such procedures, may prevent the microgasket from undergoing any loading-unloading cycles during reconnection and thus ensure the highest microgasket performance and reliability. Accordingly, the microgasket may achieve and maintain high connection/channel impedance when fully clamped.

### II. Exemplary Characterization of Mechanical Stability of Microgasket Vias

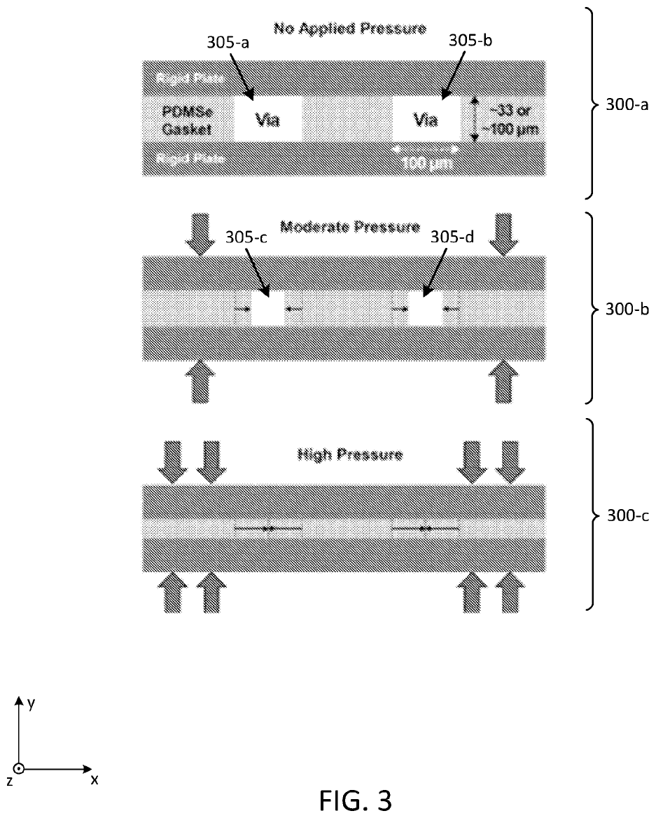

FIG. 3 illustrates a plurality of clamping configurations 300, according to one or more embodiments of the present disclosure. The application of clamping pressure is essential for implanted electrical connectors (e.g., conductive elements, microgaskets) to function as intended. Specifically, clamping forces help achieve and sustain both good electrical contact and electrical isolation between adjacent channels and the surrounding conductive saline environment. A microgasket may be utilized between clamped, mating parts to form a seal that prevents leakage of fluids, gasses, and electrical current. When higher pressure is applied, gaskets undergo a larger mechanical deformation. One or more examples described herein may utilize PDMSe as the gasket material, which may tolerate high strains.

The microgasket may include a plurality of vias 305, which may ultimately be utilized to accommodate conductive elements. Since Poisson's ratio for PDMSe is ˜0.5, the clamping pressure that results in a vertical (e.g., along the y-direction), uniaxial compression strain may also yield a large transverse strain (e.g., in the x-direction). As a result, the diameter of the vias 305 may be reduced as the clamping pressure increases. If the clamping forces are high enough, the vias 305 may be squeezed closed completely by this transverse gasket deformation. Depending on the design of the conductive elements (not shown), which may ultimately be located inside the vias 305 and may be responsible for electrically connecting opposing contacts pads, the shrinkage of vias 305 due to transverse gasket forces may interfere with their operation (e.g., block the movement of micromachined springs). To understand the mechanical behavior of microgaskets and vias 305 under large deformations, one or more test procedures may be utilized to study the dependence of these deformations on clamping pressure.

In one example of such a test procedure, each microgasket may have 49 vias 305 of the same size (100 μm diameter) and configured in a same pattern (e.g., hexagonal-close-packed arrangement with 300 μm center-to-center spacing) as contact pads on a neural interface. The microgaskets may be fabricated by spin coating and curing PDMSe on a polycarbonate sheet (e.g., the rigid plate) attached to a 100 millimeter (mm) diameter silicon wafer with adhesive tape. The polycarbonate sheet may facilitate the subsequent removal of the microfabricated silicone parts by mechanical peeling. A 30-μm-thick layer of photoresist may then be spin coated onto the silicone layer. The vias 305 may be formed by laser ablation using a picosecond laser. The photoresist sacrificial layer may then be etched away in acetone to remove debris that forms during the laser ablation process. The microfabricated microgaskets may then be peeled off the polycarbonate sheet as needed for testing.

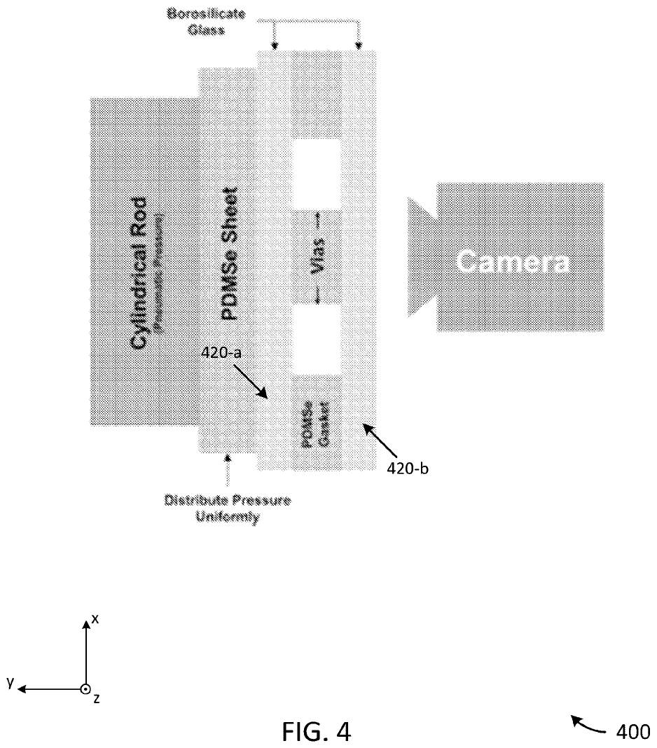

FIG. 4 illustrates a test configuration 400, according to one or more embodiments of the present disclosure. To quantify the mechanical deformation of microscale vias in a PDMSe microgasket as a function of applied clamping pressure, the microgasket may be tested using the test configuration 400, which may enable direct visual observation of the deforming microscale vias with a camera or a microscope. Specifically, the test configuration 400 may position the gasket between two vertically oriented rigid-borosilicate-transparent glass plates 420 arranged horizontally on an experimental bench. The plate 420-b may be fixed while the plate 420-a may be movable and may be pushed by a cylindrical rod connected to a pneumatic cylinder piston (not shown) to compress the microgasket. A microscope-based camera may be used to directly observe the transverse deformation of the microscale vias. The via height-to-diameter aspect ratio is an important parameter that impacts the change in via geometry observed as a function of applied pressure. In some examples, microgaskets having different thickness may be tested. For example, tests may be conducted for 100 μm thick microgaskets and 33 μm thick microgaskets. In such examples, with vias having 100 μm diameters, corresponding aspect ratios are 1 and ⅓, respectively.

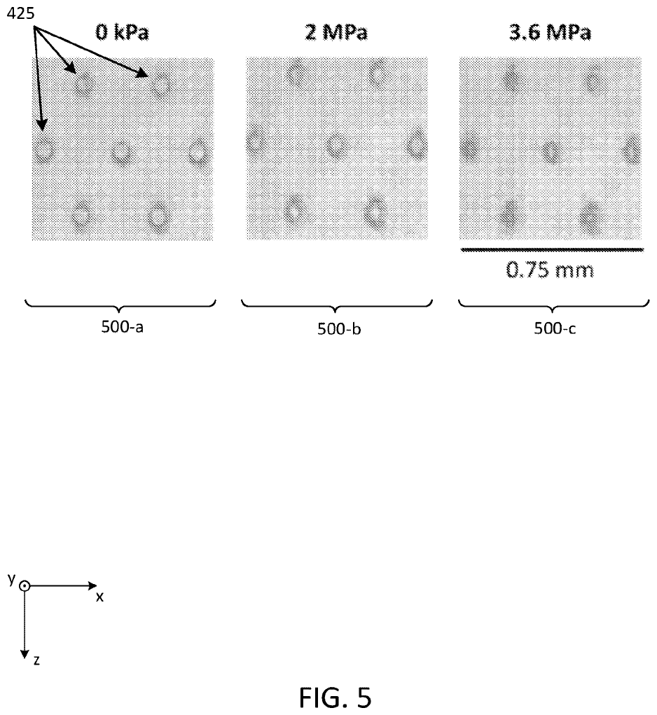

FIG. 5 illustrates examples of microgasket cross sections 500, according to one or more embodiments of the present disclosure. Each microgasket cross section 500 may include a plurality of vias 425. The cross section 500-a may illustrate a plurality of vias 425 under a first clamping pressure (e.g., 0 kilopascals (kPa)), the cross section 500-b may illustrate a plurality of vias 425 under a second clamping pressure (e.g., 2 megapascals (MPa)), and the cross section 500-c may illustrate a plurality of vias 425 under a third clamping pressure (e.g., 3.6 MPa). As shown, the area and diameter of a via 425 may decrease with increased applied pressure. At lower applied pressures, the reduction in the area of a 100-μm-diameter via 425 may be independent of microgasket thickness (e.g., with respect to the y-direction). However, as the pressure increases, thinner microgaskets (˜33 μm) that have lower thickness-to-diameter vias (i.e., aspect ratio of ⅓) may experience a lower reduction in via area than thicker microgaskets (˜100 μm) with a higher aspect ratio. Other than clamping pressure, several other factors (e.g., pad density, material hardness, pad size, surface roughness etc.) may affect the electrical isolation performance of microgaskets.

As described herein, when PDMSe microgaskets are mechanically compressed, the gasket material expands laterally into the vias 425. As the material from the compressed gasket moves into the vias 425, the diameter of the vias 425 may shrink significantly and may close off completely with the application of enough clamping pressure. Although there is an inverse linear relationship between clamping pressure applied to the microgaskets and via area (i.e., higher microgasket clamping pressure results in less via area), the slope of this relationship is dependent on the aspect ratio. Specifically, lower via thickness-to-diameter aspect ratios may result in less reduction of via area with applied pressure. In some examples, reduction in via diameter associated with clamping may improve performance. For example, the performance of the vertical-via-conduction approach (e.g., via assembly 200-a as described with reference to FIG. 2) that achieves vertical conduction through the use of conductive particles in a compressible material matrix that is packed or otherwise integrated into the original uncompressed via volume, may be improved (e.g., lateral compression of the vertical-conduction plug made of conductive particles and compressible matrix by the gasket sidewalls may result in upward and downward forces on the opposing conductive pad arrays). Similarly, the performance of the via assembly using conductive electro spun fibers may also improve with reduction in via area during clamping.

### III. Exemplary Design Considerations

Conductive elements may be capable of electrically bridging the dielectric vertical gap between the contact pads of the neural interface and the pad array of other electronic components (e.g., the header, lead extension, etc.) formed by the gasket material. The design and manufacture of the conductive elements may account for several factors (i.e., electrical conductance, integration compatibility, functional lifetime in harsh environments, contact reliability, and compressibility). Each factor is discussed in detail herein.

Electrical Conductance: Each conductive element may have an electrical conductance sufficient to be considered suitable for connectors. The conductance may be high enough that the conductive element provides a negligible voltage drop for electrical signals passing through it. If the conductance is too low, signal loss may occur. Ideally, the impedance of the conductive elements may be lower than the impedance of other elements in the signal pathway (e.g., the impedance of the trace, dielectric layer, ceramic header, and electronics). Also, a signal when it approaches the contact pad of the neural interface may have two pathways: (1) it may either leak into the adjacent channels through the interface at the surface of the gasket and contact pad array, or (2) it may go through the conductive element to finally reach the electronics. For proper connector functioning, the proportion of the latter may be far greater than the former. In some examples, conductive elements may be formed of metal, such as silver, gold, platinum, or any combination thereof. In addition to metals, other materials that exhibit high conductivity (e.g., carbon nanotubes, polymer spheres coated with metal, etc.) may be utilized.

Integration Compatibility: This refers to the process and material compatibility of the integration of the PDMS gasket and conductive elements. In some examples, a silicone-based conductive material may be utilized for forming conductive elements. The silicone-based conductive material may include conductive particles suspended in silicone. The silicone may allow for PDMS adhesion and conductive particles may allow for electrical signals to percolate through the conductive element.

Functional Lifetime in Harsh Environments: The conductive elements may be capable of withstanding a harsh environment for the duration of their functional lifetime. This refers to the fact that the conductive element function does not deteriorate (e.g., due to corrosion or material failure). Accordingly, conductive elements may be inert to corrosion in an implant environment.

Contact Reliability: The conductive elements may be capable of reliable electrical contact with the contact pads they touch. In some examples, multiple points of contact may exist between conductive elements and other components (e.g., neural interface contact pads, feedthroughs), which may allow for reliable and low-impedance connections.

Compressibility: The conductive elements may be compressible, which may enable them to withstand the force and accompanying displacement during connector operation. Additionally, compliant conductive elements may, under clamping (1) make successful contacts in the entire array and (2) prevent damage to the delicate contact pads of the neural interface. Additionally, or alternatively, the electrical conductance of the conductive elements may not deteriorate as a result of compression.

### IV. Exemplary Integration Approaches

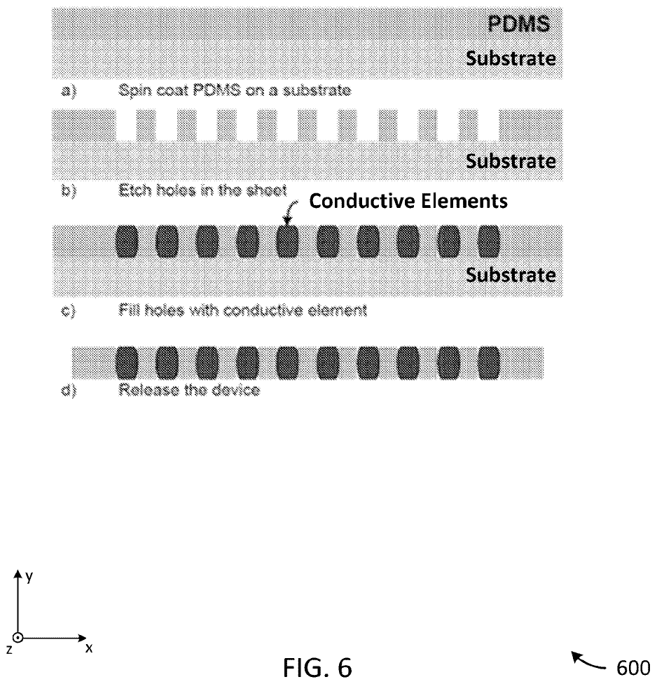

FIG. 6 illustrates an example of a fabrication process 600, according to one or more embodiments of the present disclosure. For example, the fabrication process 600 may include one or more steps (e.g., steps A through D), which may be performed sequentially. In some examples, one or more steps of the fabrication process 600 may be describe with reference to a first direction (e.g., an x-direction), a second direction (e.g., a z-direction), and a third direction (e.g., a y-direction). As shown, the first direction and the second direction may be parallel to a surface of the substrate. The third direction may be parallel to a height of the substrate. The conductive elements and the non-conductive PDMS sheet may be integrated so that they may together form a microgasket with cylindrical conductive elements surrounded by a non-conductive material (e.g., PDMSe). Multiple approaches may be used to achieve this. The fabrication process 600 may provide an illustrative example of one or more processing steps of a first approach. For example, the fabrication process 600 may include forming the gasket of PDMSe, making holes in the gasket, filling the holes with one or more compressible, conductive materials (e.g., a composite material including a dielectric material and a conductive material), and then releasing the completed microgasket including the conductive elements from the substrate. An example of this approach starts by spin-coating PDMS sheet onto a substrate, laser-etching holes in the thin PDMS sheet, and then filling these holes with conductive PDMS using a via-filling technique. The finished microgasket including conductive elements may then be released from the substrate after curing.

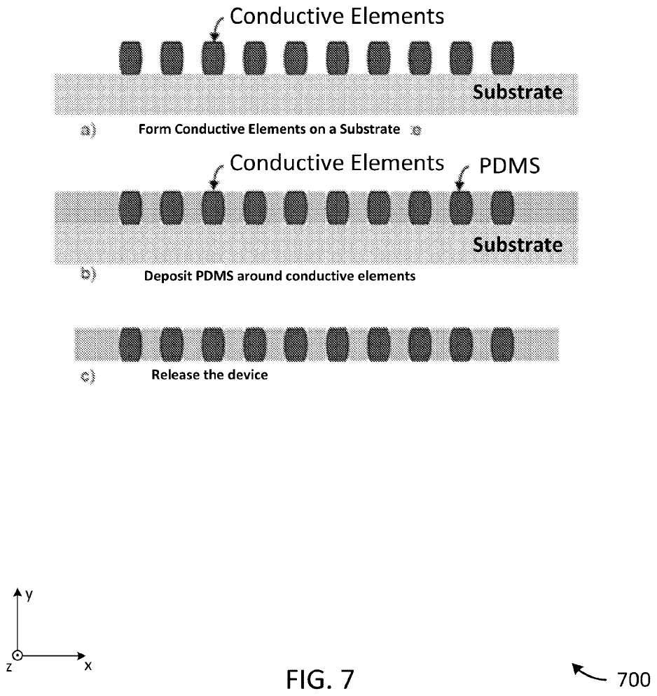

FIG. 7 illustrates an example of a fabrication process 700, according to one or more embodiments of the present disclosure. The fabrication process 700 may provide an illustrative example of one or more processing steps for a second approach. In some examples, one or more steps of the fabrication process 700 may be describe with reference to a first direction (e.g., an x-direction), a second direction (e.g., a z-direction), and a third direction (e.g., a y-direction). As shown, the first direction and the second direction may be parallel to a surface of the substrate. The third direction may be parallel to a height of the substrate. The second approach may include forming the conductive elements on the substrate, forming the PDMS material around the conductive elements such that the upper faces of the conductive elements are exposed for making electrical connections, and peeling the completed microgasket with conductive elements from the substrate. A third approach (not shown) may include developing the non-conductive PDMS and conductive elements simultaneously (e.g., using a 3D printing process).

### V. Exemplary Alignment Techniques and Design Considerations

Multiple methods may be utilized to ensure alignment between each component (e.g., between feedthroughs, conductive elements, and contact pads). In one example, a precise alignment tool (e.g., flip-chip bonder) may be utilized to align components. In another example, one or more alignment pins may be utilized to guide the vertical stacking of each layer in the connector (e.g., in the IMD). In another example, an alignment-free gasket may be utilized. For example, alignment may not be necessary for a gasket that has a very dense and uniform array of distributed conductive elements may. In such cases, one or more conductive elements may be aligned or at least partially overlap with one or more contact pads without performing an alignment procedure.

In some examples, to maintain a steady and low electrical resistance in the electrical path, the diameter of the contacts pad and/or feedthroughs may be large enough to overhang the conductive elements. In some examples, a clamping pressure may affect a quantity of successful connections. For example, increasing a clamping pressure may increase a quantity of successful connections per gasket. In some examples, an edge-to-edge pad spacing may be selected to be larger than the diameter of conductive elements, which may improve a likelihood of successful connections being made.

### VI. Exemplary Microgasket Fabrication Techniques

This section discusses the details of the process used to fabricate conductive elements as well as integrate them into the gaskets.

Pressure: Higher pressure may lead to better isolation. Hence, the ability to withstand high pressure is extremely important for the connector design. Therefore, the conductive elements may be designed to be compliant and may not lose their conductivity under high compressive stress.

Pad Separation: The minimum acceptable pad separation (edge to edge) may be 200 μm. This sets the lower limit of the conductive element pitch. Accordingly, pitch of conductive elements may provide enough gap for isolation (i.e., two adjacent conductive elements may not be shunted by a contact pad and two contact pads may not be shunted by a conductive element). Additionally, contact pad and conductive element separation may be selected based on a desired connector density or a desired footprint of the gasket.

Thickness: The thickness of the gasket may not affect electrical isolation. However, a gasket less than 60 μm thick may be difficult to handle without damaging the gasket. Thus, a thickness of the gasket may be selected to be greater than 60 μm.

Surface Roughness: Although a smoother surface of the gasket promotes higher electrical isolation, a rougher conductive element surface may reduce the amount of contact resistance between contact pads and increase their reliability (i.e., multi-point contact).

Conductive Element Diameter: A higher conductive element diameter may be selected to improve the ease of alignment, reduce contact resistance, and improve the ease of conductive element fabrication. However, a lower conductive element diameter may be selected to reduce a footprint of the connector.

### VII. Exemplary Materials and Methods of Fabrication

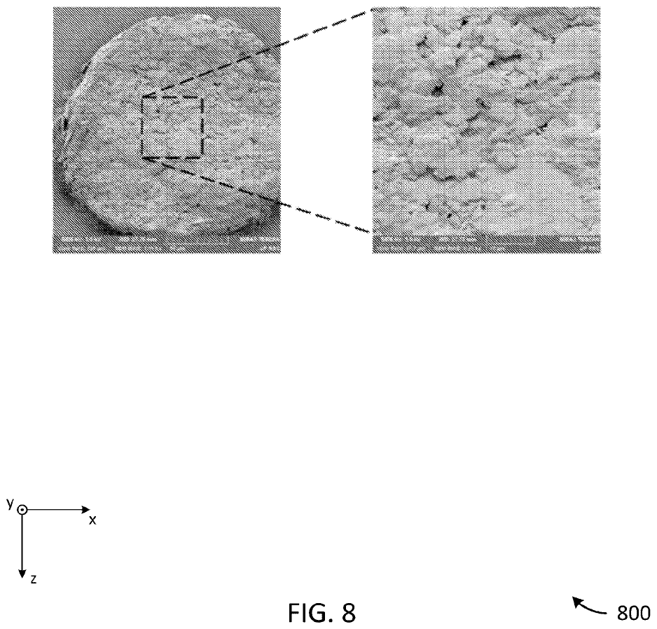

FIG. 8 illustrates an example of a conductive element 800, according to one or more embodiments of the present disclosure. As shown, FIG. 8 may illustrate one or more zoomed views of the conductive element 800. The conductive element 800 may be conductive, compressible, and capable of integration with a non-conductive PDMS material. In some examples, the conductive element 800 may be formed of one or more materials. The one or more materials may include a dielectric material and a conductive material. The conductive material may form a conductive path through the dielectric material. In some examples, the conductive material may be silver, platinum, gold, carbon, or any combination thereof. In some examples, the dielectric material may be an elastic polymer material, such as PDMSe or polyurethane.

In some examples, the conductive element 800 may be formed of a silicone material. For example, the conductive element 800 may be formed of a flexible, high-temperature, electrically conductive, silicone-based ink (e.g., an ink formed of one or more materials including a dielectric material and a conductive material). The silicone-based ink may include a silver filler. The silver filler (greater than 84% of the silicone-based ink) may provide the high electrical conductivity. The maximum sheet resistance may be 0.05 ohms per square mil (Ω/sq./mil). This ink may be compatible with screen printing, which may facilitate inexpensive, quick, and straightforward fabrication.

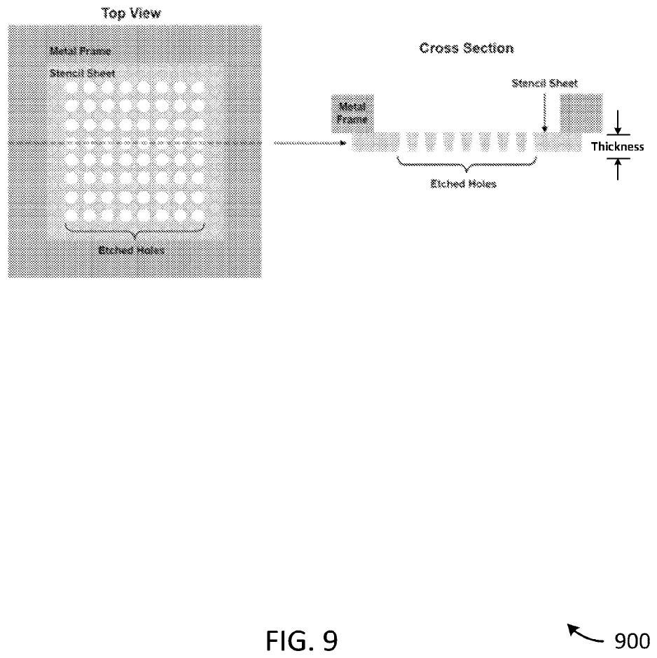

FIG. 9 illustrates an example of a stencil printing system 900, according to one or more embodiments of the present disclosure. In some examples, one or more conductive elements may be formed using stencil printing. Stencil printing is a derivative of screen printing and does not require high maintenance or special tools. Additionally, stencil printing may be performed more quickly than other processes, such as electroplating and clean-room processes. Stencil printing may also be capable of depositing cylinders of conductive polymers thicker than 60 μm.

Stencil printing is a method of patterning a substrate with a desired ink, elastomer, paste, or other material. The stencil may be a thin metal sheet with laser-etched features. The thickness chosen for the metal sheet may depend on a feature to be printed. In this case, the printed features may be small-diameter holes. Since the holes are produced using a process known as laser trepanning, the diameter of the top of the laser-etched holes may be larger than the diameter of the bottom of the holes. These cylindrical features with a taper end up becoming a frustum with a circular base. This patterned sheet may then be attached to a metal frame and stretched so that it lays extremely flat (i.e., planar to the substrate) during the stencil-printing process. In the cross-section view, the side with the larger-diameter circle is present on the bottom, whereas the side with the smaller-diameter circle is on the top (i.e., near the frame). The substrate on which the ink may be printed (i.e., a sheet of polyethylene terephthalate (PET)) may be placed under the bottom side of the stencil and a squeegee may be applied across the top side of the stencil.

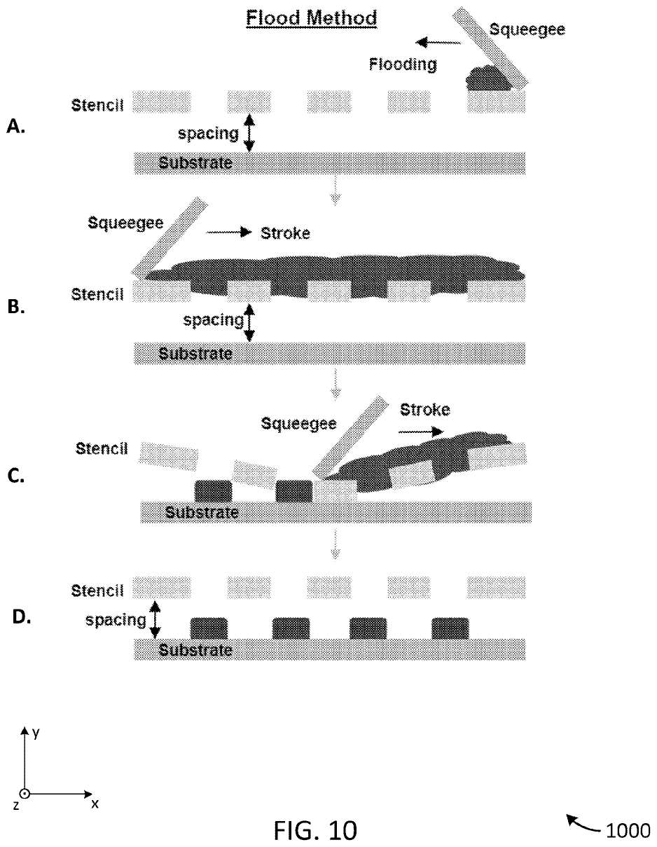

FIG. 10 illustrates an example of a flood printing system 1000, according to one or more embodiments of the present disclosure. Flood printing is a special form of stencil printing that may be used as an alternative to stencil printing. During the set-up phase of flood printing, the substrate may be placed under the bottom surface of the stencil, but these two parts may not touch. Instead, a small gap between each may be maintained with the help of some spacers. The next step is to flood the top of the stencil with conductive ink using a lightly pressed squeegee. Doing so ensures that the flooding-process starts with the patterns nearest to the user and ends with flooding the patterns farthest from the user. For simplicity, the tapered profiles of the holes are not shown. Once the ink is spread over the stencil, the stroke step may be started. During the stroke step, the squeegee may be applied at an angle with some pressure and moved with constant speed in the opposite direction of the flooding step. Therefore, on this step the squeegee may be moved towards the operator. During this step the pressure, squeegee angle, and the speed along the squeegee length, may be uniform. Step C illustrates an intermediate step in the process, where the squeegee pressure causes the initially spaced stencil and substrate to touch each other. The pressurized squeegee forces the viscous ink to flow into the patterns of the stencil. Once the squeegee has filled a hole and has moved on to the next pattern, the recently patterned area of stencil gradually starts to revert to its initial (e.g., vertically separated) position. Step D shows the printed substrate after the stroke step is completed. In some examples, the stroke step may start and finish at least 2 inches before and after the desired area to be patterned, which may improve uniformity of the printed conductive elements. Additionally, this may allow for conductive elements at the extremities of the stencil to face the same conditions as the patterns in the middle of the stencil. After the printing process is completed, the pattern may be cured at 120 degrees Celsius for two hours to remove all the solvent from the ink.

### VIII. Exemplary Stencil Printing Parameters

This section is focused on a discussion of the printing parameters and their optimal ranges. The patterns may be formed using hand printing or a printing machine. In some examples, parameter values described herein may be different for different set-ups and different inks.

Squeegee Angle: This parameter refers to the angle between the stencil and the squeegee during the stroke step. Ideally, the angle should be between 40 to 45 degrees. Printing with high angles (i.e., near 90 degrees) or low angles (i.e., near 0 degrees) may result in unfilled shapes and is not recommended.

Printing Method: This parameter refers to whether or not flooding is used during printing. Flood printing results in better prints when compared to the quality of prints without the flood step. This may not be true for shapes with different patterns or for different inks, etc. The improved outcomes may be due to the presence of abundant material around the pattern during stroke step of the flood print. The abundant material allows for the pattern to be filled more quickly and have less need for ink to be flowing.

Spacing: This parameter refers to the initial spacing between the substrate and the stencil, which is approximately 3 millimeters (mm). A lower spacing than 3 mm may result in clogging and patterns that are not able to fully release from the stencil holes. A higher spacing may result in the stencil being unable to reach the substrate during the stroke step, which may cause the ink to leak between the unsealed (i.e., masked) areas of the substrate.

Substrate Material: In some examples, a PET sheet may be used as the substrate. Using a PET sheet may be beneficial when the microgasket is released from the substrate, as silicone does not chemically bond to the PET and therefore is easy to peel. The material surface should also be cleaned with isopropyl alcohol as it may promote adhesion of ink during the printing process. A dirty PET surface may lead to print failure as ink may remain attached to the stencil instead of adhering to the substrate.

Squeegee Pressure: In some examples, printing may be performed by hand or using a printing machine. A range of 5 to 10 kilograms (kg) may be applied uniformly throughout the length of the printing operation and also with respect to time of the stroke step. Low squeegee pressures may lead to unfilled vias and high squeegee pressures may lead to thinner prints, scooping, and bleeding.

Print Speed: This parameter refers to the squeegee-movement. In some examples, speed of the print may be approximately 5 millimeters per second (mm/s). Medium or high print speeds may not give viscous inks the time they need to flow into the stencil cavities completely and could lead to unfilled vias. Also, the speed should be constant throughout the step to produce feature shapes accurately.

Squeegee Durometer, Shape, and Width: In some examples, the squeegee may be made of a polyurethane elastomer. Additionally, a hardness of the squeegee may be 70A (Shore A hardness). In some examples, a tip of the squeegee may be square, round, or v-shaped. A squeegee width may be selected such that the squeegee extends beyond both sides of the print by 2 or more inches.

Ink Viscosity: This parameter refers to the viscosity of undiluted ink. In some examples, ink viscosity may be between 16000 to 20000 centipoise (cps). In some examples, a thinner may be added to an ink to adjust the viscosity of the ink. In such examples, a quantity of thinner added to the ink may be between 2% and 4% of the ink weight. In some examples, the ink may be periodically diluted (e.g., after one or more batches) to improve viscosity.

Pattern Pitch: This parameter refers to the pitch of the holes used in the stencil pattern. Pattern pitch may be determined by electrical isolation experiments and a minimum edge-to-edge pitch (i.e., 200 μm). In some examples, smaller pitch prints may be more likely to overflow and bleed, whereas a larger distance between holes may lead to a cleaner print of the conductive elements. Some examples of edge-to-edge pitches are 400 μm, 600 μm, and 1000 μm.

Stencil Height: Stencil height may be determined based on a desired thickness of the gasket (e.g., gasket thickness may be greater than 60 μm) for handleability. In some examples, a stencil height of 100 μm may be selected.

Etched hole Diameter: Each etched hole may be formed in the shape of a frustum (e.g., having a top diameter and a bottom diameter different from the top diameter). In some examples, a difference between the bottom diameter and the top diameter may be 12 μm. In some examples, three different diameters may be utilized for etched holds (e.g., for the top diameter, for the bottom diameter, for a diameter between the top diameter and the bottom diameter). The three diameters may be 200 μm, 225 μm and 250 μm.

Conductive element Aspect Ratio: The goal is to print easily handleable (i.e., thicker) conductive elements with small footprints (i.e., high conductive element packing density). A high conductive element density may translate to a smaller conductive element pitch and a smaller conductive element diameter. Smaller-diameter and taller conductive elements may lead to a high conductive element aspect ratio. In some examples, a low-aspect ratio for conductive elements may improve printability and repeatability.

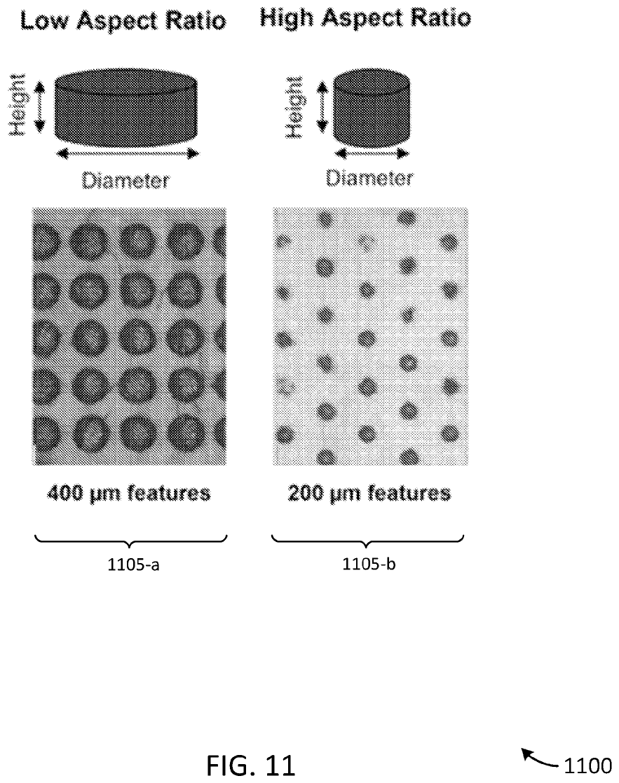

FIG. 11 illustrates example aspect ratio configurations 1100, according to one or more embodiments of the present disclosure. For example, the aspect ratio configurations 1100 may include a plurality of conductive elements 1105-a and a plurality of conductive elements 1105-b. Each conductive element of the plurality of conductive elements 1105-a may have a first aspect ratio (e.g., a low aspect ratio) and each conductive element of the plurality of conductive elements 1105-b may have a second aspect ratio (e.g., a high aspect ratio). Additionally, the aspect ratio configurations 1100 may illustrate a comparison of results when printing low-aspect-ratio and high-aspect-ratio conductive elements. The height of each of the conductive elements may be 125 μm. Each conductive element of the plurality of conductive elements 1105-a may have a 400 μm diameter and an aspect ratio of 0.31. Each conductive element of the plurality of conductive elements 1105-b may have a 200 μm diameter and aspect ratio of 0.62. As shown, the high-aspect-ratio conductive elements may be more consistent and repeatable than low-aspect-ratio conductive elements. Therefore, conductive elements described herein may have diameters within the range of 200 μm to 250 μm with heights of 100 μm. Resulting aspect ratios may be within the range of 0.5 to 0.4.

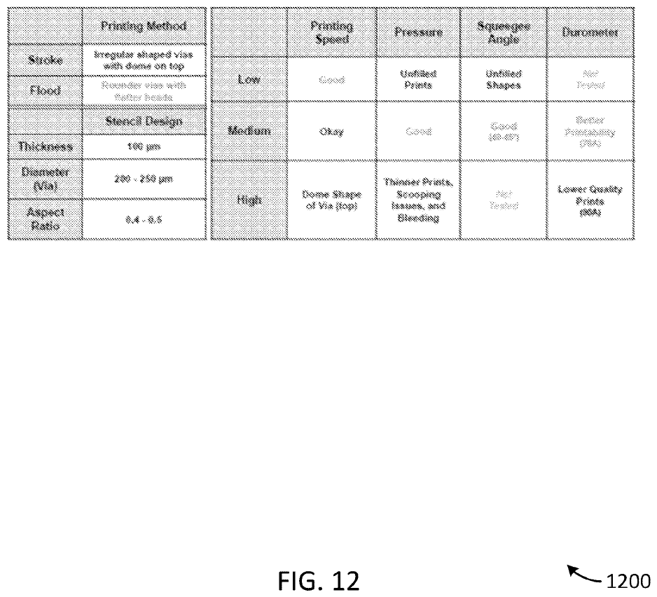

FIG. 12 illustrates an example table 1200 including parameters that may be selected for microgasket fabrication, according to one or more embodiments of the present disclosure. For example, a microgasket may be fabricated using a flood printing process, a low printing speed, a medium printing pressure, a squeegee angle within the range of 40 to 45 degrees, and a squeegee hardness of 70A. The stencil utilized for the fabrication process may have a thickness of 100 μm and hole diameters within the range of 200 μm to 250 μm, which may produce conductive elements with diameters within the range of 200 μm to 250 μm. Such parameters may result in conductive elements with aspect ratios within the range of 0.4 to 0.5.

### IX. Exemplary Conductive Element and PDMS Integration

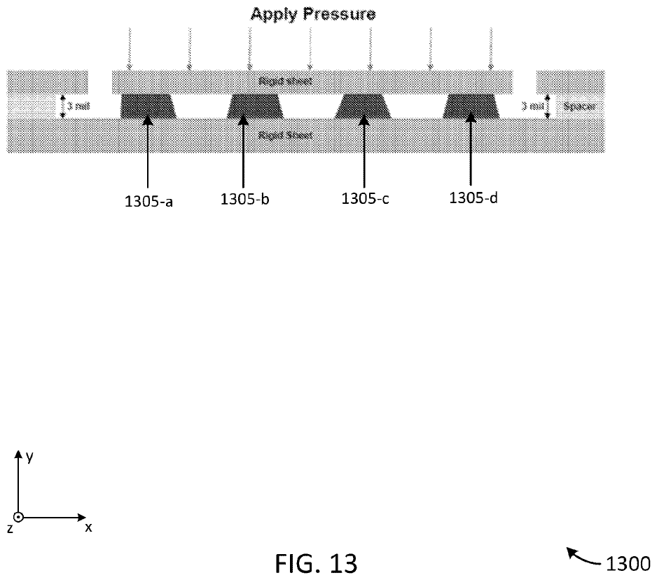

FIG. 13 illustrates an example of a microgasket fabrication system 1300, according to one or more embodiments of the present disclosure. The microgasket fabrication system 1300 may be described with reference to a coordinate system including a first direction (e.g., the x-direction), a second direction (e.g., the z-direction), and a third direction (e.g., the y-direction). The microgasket fabrication system may include one or more rigid sheets. For example, one or more conductive elements 1305 may be formed on a first rigid sheet (e.g., a substrate, a bottom rigid sheet with respect to the y-direction). A second rigid sheet (e.g., a planar component) may then be placed on top of the one or more conductive elements 1305 and used to compress the one or more conductive elements 1305 in the negative y-direction.

In some examples, the first rigid sheet and the second rigid sheet may be formed of a plastic material. In some other examples, the first rigid sheet and the second rigid sheet may be formed of acrylic, stainless steel, aluminum, or ceramic. In some examples, the one or more conductive elements may have respective first height dimensions (e.g., parallel to the y-direction) prior to being compressed by the second rigid sheet and respective second height dimensions when compressed by the second rigid sheet. Accordingly, the rigid sheet may be used to adjust height dimensions of conductive elements 1305.

In some examples, the microgasket fabrication system 1300 may be utilized to level a height (e.g., parallel to the y-direction) of conductive elements 1305. For example, prior to compressing the plurality of conductive elements 1305, one or more of the conductive elements 1305 may have different heights. Accordingly, compressing the plurality of conductive elements 1305 may deform the plurality of conductive elements 1305 to have a same height or respective heights within a threshold range of heights.

In some examples, the microgasket fabrication system 1300 may integrate the conductive elements 1305 with a PDMS material (e.g., a dielectric material), among other examples. After the printing of the conductive elements 1305, the goal is to integrate them with the PDMS polymer in a way that the conductive ink and the PDMS elastomer have good adhesion, the top faces of all the conductive elements 1305 may be exposed, and a height of all of the conductive elements 1305 may be the same (e.g., 3 mil). To achieve this, the conductive elements top surfaces are flattened to minimize effects like scooping, dome shape, height mismatch, etc. In some examples, flattening the top surface of conductive elements may improve electrical conductivity between the conductive elements and surfaces in contact with the conductive elements, such as contact pads of a neural interface. In some examples, flattening the top surfaces of conductive elements may also enable any conductive element height mismatches to be eliminated by leveling the conductive elements 1305. In some examples, the conductive elements 1305 may be arranged along the x-direction (e.g., a first direction) and the z-direction (e.g., a second direction).

The conductive ink utilized to form the conductive elements 1305 may be reworkable. This property allows the ink to be reshaped with heat even after curing. The 100-μm-diameter stencil holes may form conductive elements 1305 having heights between 78 and 92 μm. Since the conductive elements 1305 may all be more than 3 mil (e.g., 76.2 μm) in height, the conductive elements 1305 may be flattened down to 3 mil, and all reworked conductive elements 1305 may have the same height and flattened top surfaces. This may be accomplished by applying a rigid sheet (i.e., a slab of smooth acrylic, a planar component) on the top side and bottom side of the conductive elements 1305, while using one or more 3-mil-thick spacers at the edges. Accordingly, respective heights (e.g., respective second height dimensions) of the conductive elements 1305 may be based on a height dimension of the one or more spacers. For example, the rigid sheet (e.g., the planar component) may be moved downward (e.g., along the y-direction) until it contacts the one or more spacers. For simplicity, the PET substrate and the bottom acrylic slab is illustrated as one rigid sheet. The entire assembly may be clamped, which may apply pressure to the conductive elements 1305. For example, the rigid sheet may apply a force to the conductive elements 1305 in the negative y-direction (e.g., a third direction). This is shown in FIG. 13 as pressure being applied by the top rigid sheet.

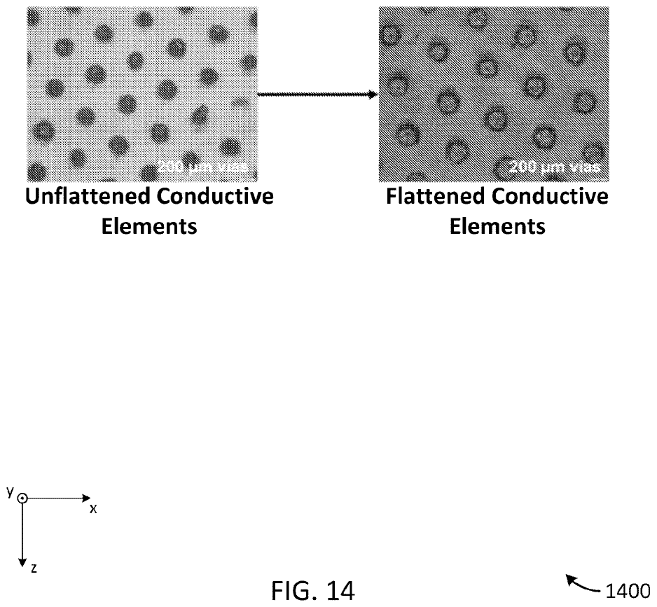

FIG. 14 illustrates examples of conductive element configurations 1400, according to one or more embodiments of the present disclosure. The conductive element configurations 1400 may illustrate a plurality of unflattened conductive elements and a plurality of flattened conductive elements. For example, the conductive element configurations 1400 may illustrate a comparison before and after the conductive elements are flattened. The flattening corrects the height (e.g., with respect to the y-direction) mismatch, scooping spikes at the periphery, dome shape of the top surface, and increases the top surface area due to the frustum shape of the conductive elements. All of these modifications may result in more points of contact, lower contact resistance, and higher contact stability.

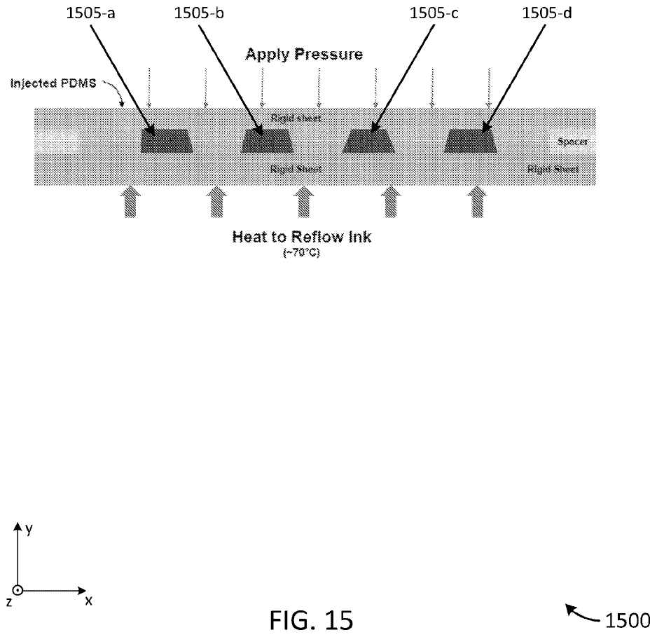

FIG. 15 illustrates an example of a microgasket fabrication system 1500, according to one or more embodiments of the present disclosure. The microgasket fabrication system 1500 may be described with reference to a coordinate system including a first direction (e.g., the x-direction), a second direction (e.g., the z-direction), and a third direction (e.g., the y-direction). The microgasket fabrication system may include one or more rigid sheets. For example, one or more conductive elements 1505 may be formed on a first rigid sheet (e.g., a substrate, a bottom rigid sheet with respect to the y-direction). A second rigid sheet (e.g., a planar component) may then be placed on top of the one or more conductive elements 1505 and used to compress the one or more conductive elements 1505 in the negative y-direction.

In some examples, the microgasket fabrication system 1500 may be utilized to integrate the conductive elements 1505 with a PDMS material (e.g., the PDMS gasket, a dielectric material), among other examples. This may be accomplished by injecting the uncured PDMS directly into the clamped assembly including the conductive elements 1505 (e.g., injecting the dielectric material between the substrate and the planar component). In some examples, a PDMS resin may be mixed with a platinum based catalyst. The solution may then be desiccated with a vacuum to remove any air bubbles from the solution. The solution may then be loaded into a syringe while taking care to not form any additional air bubbles. The syringe may then be connected through the left hole of the top rigid plate of the microgasket fabrication system using a luer-lock fitting. The PDMS-filled syringe (e.g., the solution-filled syringe) may then slowly inject the PDMS into the 3-mil-diameter cavity of the clamped assembly (e.g., forming a dielectric layer around and in contact with the plurality of conductive elements 1505). After some time, the slowly moving PDMS may fill the entire assembly and it may reach the hole of right side of the top rigid plate. Finally, the PDMS-filled assembly may be heated to 70 degrees Celsius for two hours to cure the PDMS and also to reshape and flatten the conductive elements 1505. As shown, the top rigid plate may cover the top surface of the conductive elements 1505 during filling and therefore PDMS may not encapsulate the top areas of the conductive elements 1505.

Although the ink may be flattened and reworked as shown in FIG. 13, it may not cure until the heat is applied as shown in FIG. 15. The top and bottom rigid sheet used during conductive element flattening may be transparent, which may enable the process of flowing PDMS into the 3-mil-thick cavity to be observed. In some examples, the rigid sheets may be formed of an acrylic material. In some examples, acrylic may be selected as a material for the rigid sheets as a result of its surface finish and poor adhesion to PDMS (e.g., so that the gasket may be detached from the rigid sheet). Additionally, the surface finish of the acrylic rigid sheet may improve channel-to-channel isolation in the gasket.

After injecting the PDMS and curing the PDMS, the assembly may be placed in a room temperature environment for a duration (e.g., 10 minutes), which may enable the assembly to cool to room temperature. The completed gasket may then be removed from the assembly (e.g., the substrate and the planar component may be removed). In some examples, the assembly may simultaneously form multiple gaskets. In some examples, a thin layer of plastic or metal may be placed between the gasket and the substrate to facilitate removal of the completed gasket from the substrate. Similarly, a thin layer of plastic or metal may be placed between the gasket and the upper rigid sheet to facilitate removal of the completed gasket.

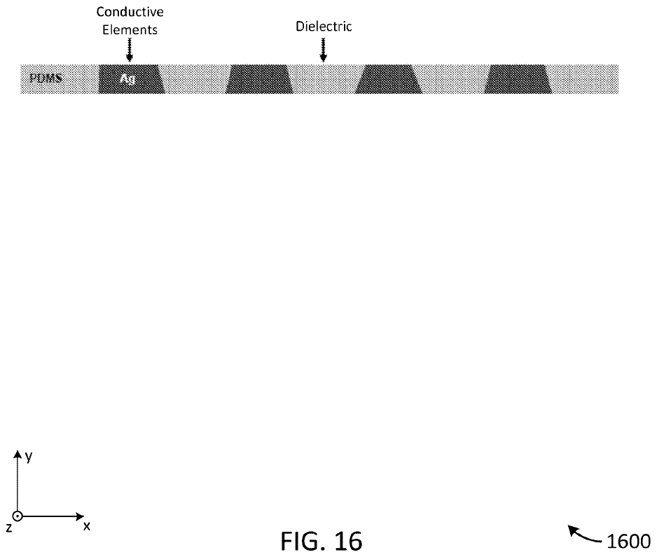

FIG. 16 illustrates an example of a microgasket 1600, according to one or more embodiments of the present disclosure. The microgasket 1600 may include a plurality of conductive elements, which may be formed of silver or any other conductive material. The microgasket 1600 may include a dielectric material, such as PDMS, that is adhered to the conductive elements.

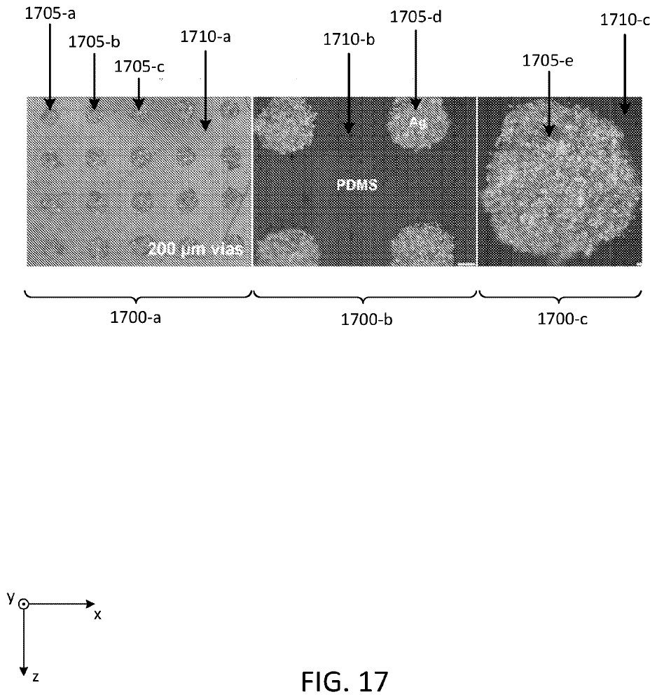

FIG. 17 illustrates examples of microgasket images 1700, according to one or more embodiments of the present disclosure. For example, the microgasket images 1700 may show various sections or views of a completed microgasket including conductive elements 1705. Each microgasket image 1700 may include views of one or more conductive elements 1705 and the PDMS gasket 1710. In some examples, each conductive element 1705 may include one or more materials, such as silver. Additionally, or alternatively, each conductive element 1705 may have a diameter of 200 μm. As shown, top surfaces of conductive elements 1705 (e.g., formed of silver ink) are flattened and the gasket surface is smooth. Similar characteristics may be observed on the reverse side of the PDMS gasket not shown in FIG. 17.

### Exemplary Technical Implementation of Various Embodiments

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium, storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises a combination of computer program products and hardware performing certain steps or operations.

Embodiments of the present disclosure are described with reference to example operations, steps, processes, blocks, and/or the like. Thus, it should be understood that each operation, step, process, block, and/or the like may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some exemplary embodiments, retrieval, loading, and/or execution may be performed in parallel such that multiple instructions are retrieved, loaded, and/or executed together. Thus, such embodiments may produce specifically configured machines performing the steps or operations specified in the block diagrams and flowchart illustrations. Accordingly, the block diagrams and flowchart illustrations support various combinations of embodiments for performing the specified instructions, operations, or steps.

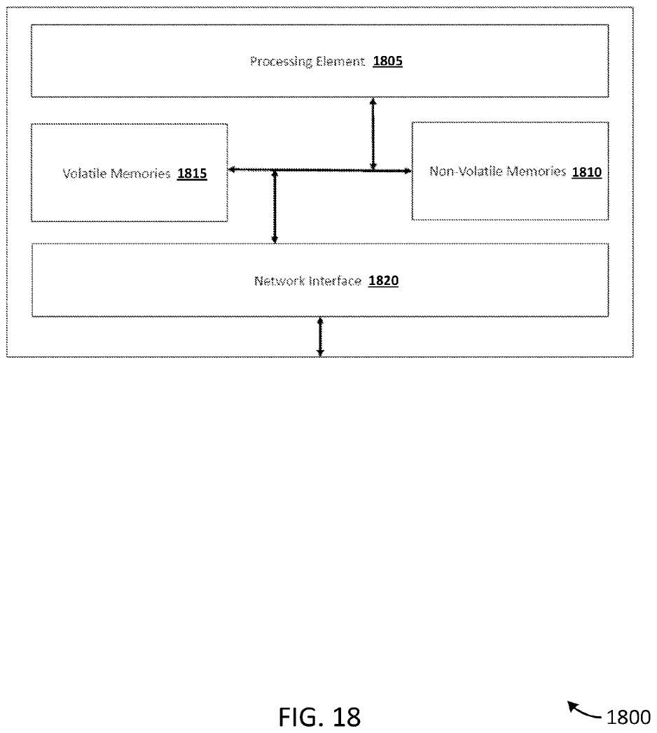

FIG. 18 provides a schematic of an exemplary apparatus 1800 that may be used in accordance with various embodiments of the present disclosure. In particular, the apparatus 1800 may be configured to perform various example operations described herein that result in the formation or characterization of a microgasket, or one or more components of a microgasket assembly. In some example embodiments, the apparatus 1800 may be embodied by a manufacturing device, such as a printing machine, that performs one or more operations as described herein.

In general, the terms computing entity, entity, device, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes may be performed on data, content, information, and/or similar terms used herein interchangeably.

Although illustrated as a single computing entity, those of ordinary skill in the field should appreciate that the apparatus 1800 shown in FIG. 18 may be embodied as a plurality of computing entities, tools, and/or the like operating collectively to perform one or more processes, methods, and/or steps. As just one non-limiting example, the apparatus 1800 may comprise a plurality of individual data tools, each of which may perform specified tasks and/or processes.

Depending on the embodiment, the apparatus 1800 may include one or more network and/or communications interfaces 1820 for communicating with various computing entities, such as by communicating data, content, information, and/or similar terms used herein interchangeably that may be transmitted, received, operated on, processed, displayed, stored, and/or the like. Thus, in certain embodiments, the apparatus 1800 may be configured to receive data from one or more data sources and/or devices, as well as receive data indicative of input, for example, from a device.

The networks used for communicating may include, but are not limited to, any one or a combination of different types of suitable communications networks such as, for example, cable networks, public networks (e.g., the Internet), private networks (e.g., frame-relay networks), wireless networks, cellular networks, telephone networks (e.g., a public switched telephone network), or any other suitable private and/or public networks. Further, the networks may have any suitable communication range associated therewith and may include, for example, global networks (e.g., the Internet), MANs, WANs, LANs, or PANs. In addition, the networks may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof, as well as a variety of network devices and computing platforms provided by network providers or other entities.

Accordingly, such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the apparatus 1800 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), 5G New Radio (5G NR), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The apparatus 800 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

In addition, in various embodiments, the apparatus 1800 includes or is in communication with one or more processing elements 1805 (also referred to as processors, processing circuitry, and/or similar terms used herein interchangeably) that communicate with other elements within the apparatus 1800 via a bus, for example, or network connection. As will be understood, the processing element 1805 may be embodied in several different ways. For example, the processing element 1805 may be embodied as one or more complex programmable logic devices (CPLDs), microprocessors, multi-core processors, coprocessing entities, application-specific instruction-set processors (ASIPs), and/or controllers. Further, the processing element 1805 may be embodied as one or more other processing devices or circuitry. The term circuitry may refer to an entirely hardware embodiment or a combination of hardware and computer program products. Thus, the processing element 1805 may be embodied as integrated circuits, application specific integrated circuits (ASICs), field programmable gate arrays (FPGAs), programmable logic arrays (PLAs), hardware accelerators, other circuitry, and/or the like.

As will therefore be understood, the processing element 1805 may be configured for a particular use or configured to execute instructions stored in volatile or non-volatile media or otherwise accessible to the processing element 1805. As such, whether configured by hardware, computer program products, or a combination thereof, the processing element 1805 may be capable of performing steps or operations according to embodiments of the present disclosure when configured accordingly.

In various embodiments, the apparatus 1800 may include or be in communication with non-volatile media (also referred to as non-volatile storage, memory, memory storage, memory circuitry, and/or similar terms used herein interchangeably). For instance, the non-volatile storage or memory may include one or more non-volatile storage or non-volatile memory media 1810 such as hard disks, ROM, PROM, EPROM, EEPROM, flash memory, MMCs, SD memory cards, Memory Sticks, CBRAM, PRAM, FeRAM, RRAM, SONOS, racetrack memory, and/or the like. As will be recognized, the non-volatile storage or non-volatile memory media 1810 may store files, databases, database instances, database management system entities, images, data, applications, programs, program modules, scripts, source code, object code, byte code, compiled code, interpreted code, machine code, executable instructions, and/or the like. The terms database, database instance, database management system entity, and/or similar terms used herein interchangeably and in a general sense refer to a structured or unstructured collection of information/data that is stored in a computer-readable storage medium.

In particular embodiments, the non-volatile memory media 1810 may also be embodied as a data storage device or devices, as a separate database server or servers, or as a combination of data storage devices and separate database servers. Further, in some embodiments, the non-volatile memory media 1810 may be embodied as a distributed repository such that some of the stored information/data is stored centrally in a location within the system and other information/data is stored in one or more remote locations. Alternatively, in some embodiments, the distributed repository may be distributed over a plurality of remote storage locations only. As already discussed, various embodiments contemplated herein use data storage in which some or all of the information/data required for various embodiments of the disclosure may be stored.

In various embodiments, the apparatus 1800 may further include or be in communication with volatile media (also referred to as volatile storage, memory, memory storage, memory circuitry, and/or similar terms used herein interchangeably). For instance, the volatile storage or memory may also include one or more volatile storage or volatile memory media 1815 as described above, such as RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like.

As will be recognized, the volatile storage or volatile memory media 1815 may be used to store at least portions of the databases, database instances, database management system entities, data, images, applications, programs, program modules, scripts, source code, object code, byte code, compiled code, interpreted code, machine code, executable instructions, and/or the like being executed by, for example, the processing element 1805. Thus, the databases, database instances, database management system entities, data, images, applications, programs, program modules, scripts, source code, object code, byte code, compiled code, interpreted code, machine code, executable instructions, and/or the like may be used to control certain aspects of the operation of the apparatus 1800 with the assistance of the processing element 1805 and operating system.

As will be appreciated, one or more of the computing entity's components may be located remotely from other computing entity components, such as in a distributed system. Furthermore, one or more of the components may be aggregated, and additional components performing functions described herein may be included in the apparatus 1800. Thus, the apparatus 800 may be adapted to accommodate a variety of needs and circumstances.

### Conclusion

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A method comprising:
forming a plurality of conductive elements on a surface of a substrate, the plurality of conductive elements arranged along a first direction parallel to the surface of the substrate and a second direction parallel to the surface of the substrate, wherein respective first height dimensions of respective conductive elements are parallel to a third direction;
compressing, in the third direction, the plurality of conductive elements using a planar component, wherein the compressing adjusts the respective first height dimensions to respective second height dimensions;
injecting a dielectric material between the substrate and the planar component, wherein injecting the dielectric material forms a dielectric layer around and in contact with the plurality of conductive elements; and
removing the substrate and the planar component.

2. The method of claim 1, further comprising:
positioning a stencil layer comprising a plurality of cavities a distance above the surface of the substrate with respect to the third direction, wherein forming the plurality of conductive elements comprises depositing, through the plurality of cavities, one or more materials onto the surface of the substrate.

3. The method of claim 2, wherein the one or more materials comprise the dielectric material and a conductive material, wherein the conductive material forms a conductive path through the dielectric material.

4. The method of claim 3, wherein the dielectric material comprises an elastic polymer material.

5. The method of claim 3, wherein the conductive material comprises silver, platinum, gold, or carbon.

6. The method of claim 4, wherein the dielectric material comprises polydimethylsiloxane or polyurethane.

7. The method of claim 1, further comprising:
positioning one or more spacers between the planar component and the substrate, wherein the planar component is in contact with the one or more spacers for the compressing.

8. The method of claim 1, further comprising:
heating the plurality of conductive elements and the dielectric material, wherein the heating cures the plurality of conductive elements and the dielectric material.

9. The method of claim 8, wherein heating the plurality of conductive elements and compressing the plurality of conductive elements adjusts the respective first height dimensions to the respective second height dimensions.

10. The method of claim 8, wherein the dielectric layer and the plurality of conductive elements have a same height dimension parallel to the third direction based at least in part on the heating.

11. The method of claim 8, wherein an electrical conductance between a conductive element of the plurality of conductive elements and an electrical contact of a neural interface is based at least in part on a flatness of a surface of the conductive element, wherein the compressing flattens the surface of the conductive element.

12. The method of claim 8, wherein, subsequent to curing the plurality of conductive elements, the respective second height dimensions of the respective conductive elements are based at least in part on respective height dimensions of one or more spacers.

13. The method of claim 1, wherein the planar component and the substrate are rigid.

14. The method of claim 1, wherein the planar component and the substrate are formed of a plastic material.

15. The method of claim 1, wherein the planar component and the substrate are formed of acrylic, stainless steel, aluminum, or ceramic.

16. The method of claim 1, wherein one or more surfaces of the planar component are coated with a layer configured to prevent adhesion between (i) the planar component and the plurality of conductive elements and (ii) the planar component and the dielectric material.

17. The method of claim 1, wherein one or more surfaces of the substrate are coated with a layer configured to prevent adhesion between (i) the substrate and the plurality of conductive elements and (ii) the substrate and the dielectric material.

18. The method of claim 17, wherein the layer is formed of a metal material or a plastic material.

19. An apparatus comprising:
at least one processor; and
at least one memory storing instructions that, when executed by the at least on processor, cause the apparatus to:
form a plurality of conductive elements on a surface of a substrate, the plurality of conductive elements arranged along a first direction parallel to the surface of the substrate and a second direction parallel to the surface of the substrate, wherein respective first height dimensions of respective conductive elements are parallel to a third direction;
compress, in the third direction, the plurality of conductive elements using a planar component, wherein the compressing adjusts the respective first height dimensions to respective second height dimensions;
inject a dielectric material between the substrate and the planar component, wherein injecting the dielectric material forms a dielectric layer around and in contact with the plurality of conductive elements; and
remove the substrate and the planar component.

20. An apparatus comprising:
an enclosure component comprising a cavity for a plurality of electronic components, wherein (i) a height of the enclosure component is parallel to a first direction, (ii) a width of the enclosure component is parallel to a second direction, and (iii) a depth of the enclosure component is parallel to a third direction;
a header in contact with the enclosure component, the header comprising a first plurality of cavities extending through the header in the first direction;
a first plurality of conductive elements formed in the first plurality of cavities, wherein one or more electronic components of the plurality of electronic components are electrically coupled with one or more conductive elements of the first plurality of conductive elements;
a gasket in contact with a top surface of the header with respect to the first direction, the gasket comprising a second plurality of cavities extending through the gasket in the first direction;
a second plurality of conductive elements formed in the second plurality of cavities, wherein the second plurality of conductive elements are in contact with the first plurality of conductive elements; and
an interface component in contact with a top surface of the gasket with respect to the first direction, the interface component comprising a plurality of contact pads in contact with the second plurality of conductive elements.
